(19) United States
(12) Patent Application Publication
(10) Pub. No.: US 2026/0334083 A1
(43) Pub. Date: Oct. 22, 2026

(54) PIEZOELECTRIC VIBRATOR

(71) Applicant: Murata Manufacturing Co., Ltd., Nagaokakyo-shi (JP)

(72) Inventor: Ryuichi KAWAI, Nagaokakyo-shi (JP)

(21) Appl. No.: 19/710,883

(22) Filed: Jun. 17, 2026

Related U.S. Application Data
(63) Continuation of application No. PCT/JP2024/037770, filed on Oct. 23, 2024.

(30) Foreign Application Priority Data
Jan. 9, 2024 (JP) 2024-001358

(51) Int. Cl. H10N 30/20; H10N 30/88

(52) U.S. Cl. CPC H10N 30/202; H10N 30/88

(57) ABSTRACT

A piezoelectric vibrator that includes: a piezoelectric vibration element including: a vibration part, a holding part disposed in at least a part of a frame-shaped region surrounding the vibration part such that the holding part has a gap from the vibration part, and a support arm coupling the vibration part to the holding part to support the vibration part; a first substrate opposing a first side of the piezoelectric vibration element; a second substrate opposing a second side of the piezoelectric vibration element opposite from the first substrate; a first bonding part bonding the holding part of the piezoelectric vibration element to the first substrate; a second bonding part bonding the holding part of the piezoelectric vibration element to the second substrate; and a reinforcement part comprising resin and covering at least a part of the support arm.

### CROSS REFERENCE TO RELATED APPLICATIONS

The present application is a continuation of International application No. PCT/JP2024/037770, filed Oct. 23, 2024, which claims priority to Japanese Patent Application No. 2024-001358, filed Jan. 9, 2024, the entire contents of each of which are incorporated herein by reference.

### TECHNICAL FIELD

The present disclosure relates to a piezoelectric vibrator.

### BACKGROUND ART

Piezoelectric vibrators are used in timing devices, sensors, oscillators, and the like in various electronic devices such as mobile communication terminals, communication base stations, and home appliances. A piezoelectric vibrator includes a sealed piezoelectric vibration element, and the piezoelectric vibration element includes a piezoelectric substrate having a pair of main surfaces and a pair of excitation electrodes disposed on the pair of main surfaces of the piezoelectric substrate.

For example, Patent Document 1 discloses a piezoelectric device including a piezoelectric vibrating piece, and a lid portion and a base portion with the piezoelectric vibrating piece sandwiched therebetween. This piezoelectric vibrating piece includes a vibrator, a framing portion surrounding the vibrator, and a connecting portion connecting the vibrator and the framing portion. An excitation electrode is disposed on the vibrator, a connection electrode is disposed on the framing portion, and an extraction electrode is disposed on the connecting portion.

Patent Document 1: Japanese Unexamined Patent Application Publication No. 2014-176071

### SUMMARY OF THE DISCLOSURE

In the piezoelectric device described in Patent Document 1, when impact such as from a fall or vibration is applied, stress is concentrated at a connection between the framing portion and the connecting portion, and the piezoelectric vibrating piece may be damaged.

The present disclosure is made in view of such circumstances, and an object thereof is to provide a piezoelectric vibrator capable of achieving improved reliability.

According to an aspect of the present disclosure, a piezoelectric vibrator includes: a piezoelectric vibration element including: a vibration part, a holding part disposed in at least a part of a frame-shaped region surrounding the vibration part such that the holding part has a gap from the vibration part, and a support arm coupling the vibration part to the holding part to support the vibration part; a first substrate opposing a first side of the piezoelectric vibration element; a second substrate opposing a second side of the piezoelectric vibration element opposite from the first substrate; a first bonding part bonding the holding part of the piezoelectric vibration element to the first substrate; a second bonding part bonding the holding part of the piezoelectric vibration element to the second substrate; and a reinforcement part comprising resin and covering at least a part of the support arm.

According to the present disclosure, a piezoelectric vibrator capable of achieving improved reliability can be provided.

### BRIEF DESCRIPTION OF THE DRAWINGS

FIG. 1 is an exploded perspective view of a crystal vibrator according to a first embodiment.

FIG. 2 is a certain sectional view taken along line II-II of the crystal vibrator described in the first embodiment.

FIG. 3 is a certain sectional view taken along line III-III of the crystal vibrator described in the first embodiment.

FIG. 4 is a plan view of the crystal vibrator according to the first embodiment.

FIG. 5 is a plan view of a crystal vibration element according to the first embodiment.

FIG. 6 is a plan view of a lower lid according to the first embodiment.

FIG. 7 is a certain sectional view of a crystal vibrator according to a second embodiment.

FIG. 8 is a certain sectional view of a crystal vibrator according to a third embodiment.

FIG. 9 is a plan view of the crystal vibrator according to the third embodiment.

FIG. 10 is a certain sectional view of a crystal vibrator according to a fourth embodiment.

FIG. 11 is a certain sectional view of a crystal vibrator according to a fifth embodiment.

FIG. 12 is a plan view of the crystal vibrator according to the fifth embodiment.

FIG. 13 is a certain sectional view of a crystal vibrator according to a sixth embodiment.

FIG. 14 is a plan view of a lower lid according to the sixth embodiment.

### DESCRIPTION OF THE PREFERRED EMBODIMENTS

Embodiments of the present disclosure will be described below. In the following description with reference to the drawings, the same or similar components are denoted by the same or similar reference characters. The drawings are illustrative and the dimensions and shape of each part are schematic, and the technical scope of the present disclosure should not be interpreted as being limited to the embodiments.

In each drawing, an orthogonal coordinate system consisting of an X axis, a Y′ axis, and a Z′ axis may be provided for convenience to clarify the mutual relationship of the drawings and to aid understanding of the positional relationship of members. The X axis, the Y′ axis, and the Z′ axis correspond between the drawings. The X axis, the Y′ axis, and the Z′ axis correspond to respective crystallographic axes of a crystal substrate 11 described later. The X axis corresponds to an electrical axis (polar axis) of a crystal, a Y axis corresponds to a mechanical axis of the crystal, and a Z axis corresponds to an optical axis of the crystal. The Y′ axis and the Z′ axis are axes obtained by rotating the Y axis and the Z axis, respectively, counterclockwise about the X axis by θ degrees, when viewed from a positive side in an X axis direction.

In the following description, a direction parallel to the X axis is referred to as the “X axis direction”, a direction parallel to the Y′ axis is referred to as a “Y′ axis direction”, and a direction parallel to the Z′ axis is referred to as a “Z′ axis direction”. Further, a direction of a tip of an arrow of each of the X axis, the Y′ axis, and the Z′ axis is referred to as “positive” or “+ (plus)”, and a direction opposite to the arrow is referred to as “negative” or “− (minus)”. Note that, for convenience, the +Y′ axis direction is described as an upper direction and the −Y′ axis direction is described as a lower direction. However, the up-down direction of a crystal vibration element 10 and a crystal vibrator 1 is not limited. In addition, a plane defined by the X axis and the Z′ axis is referred to as a Z′-X plane, and the same applies to planes defined by other axes.

### First Embodiment

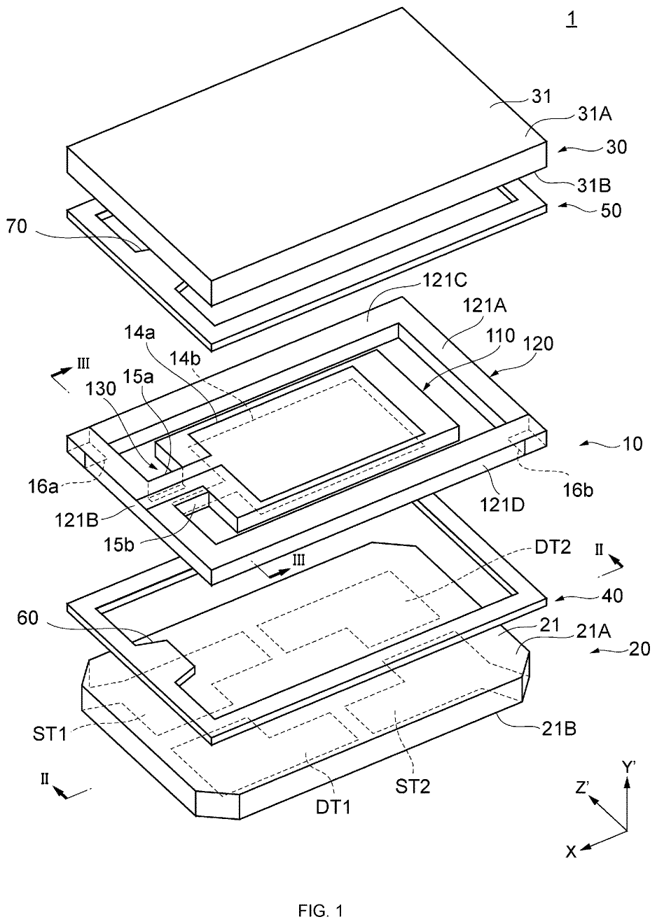

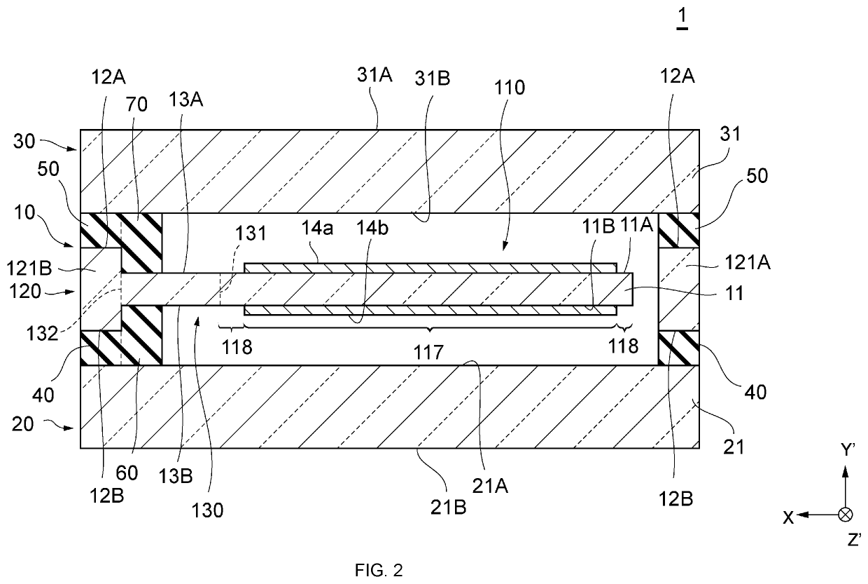

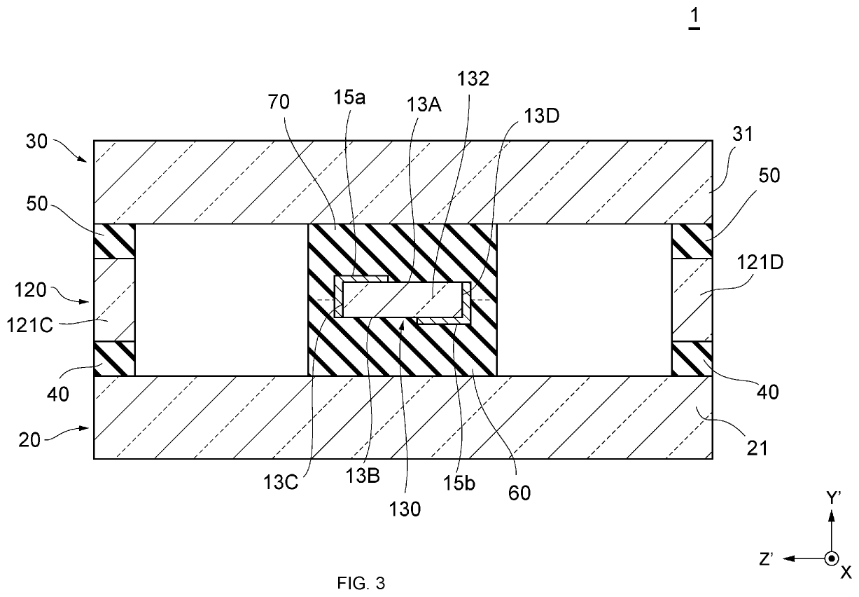

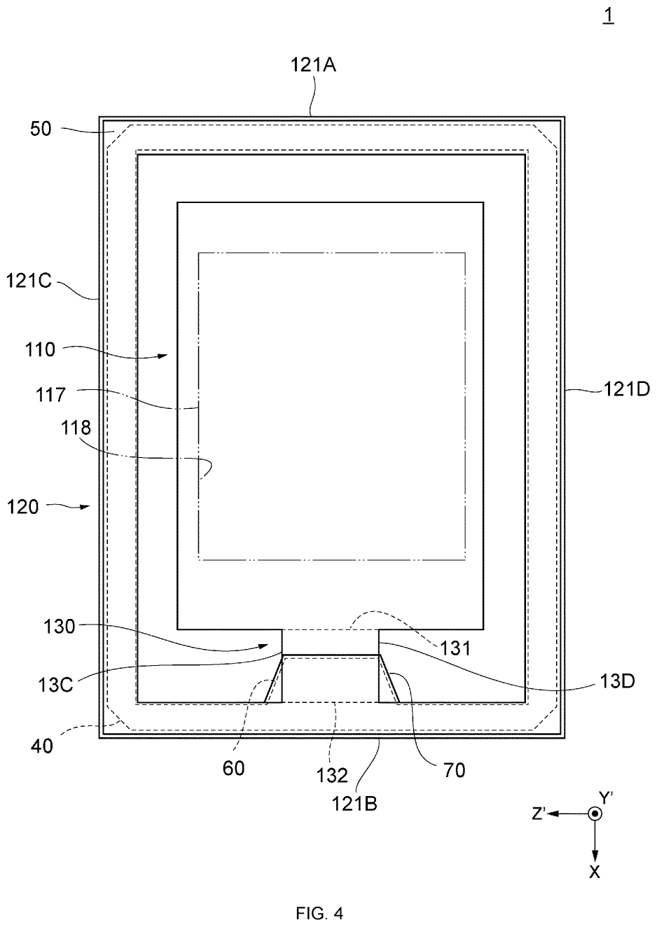

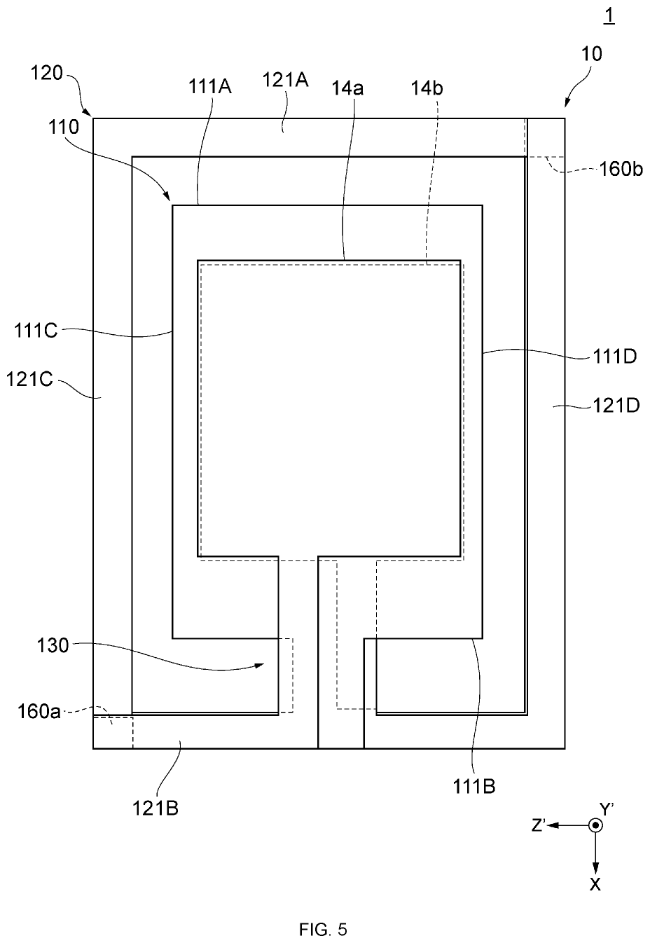

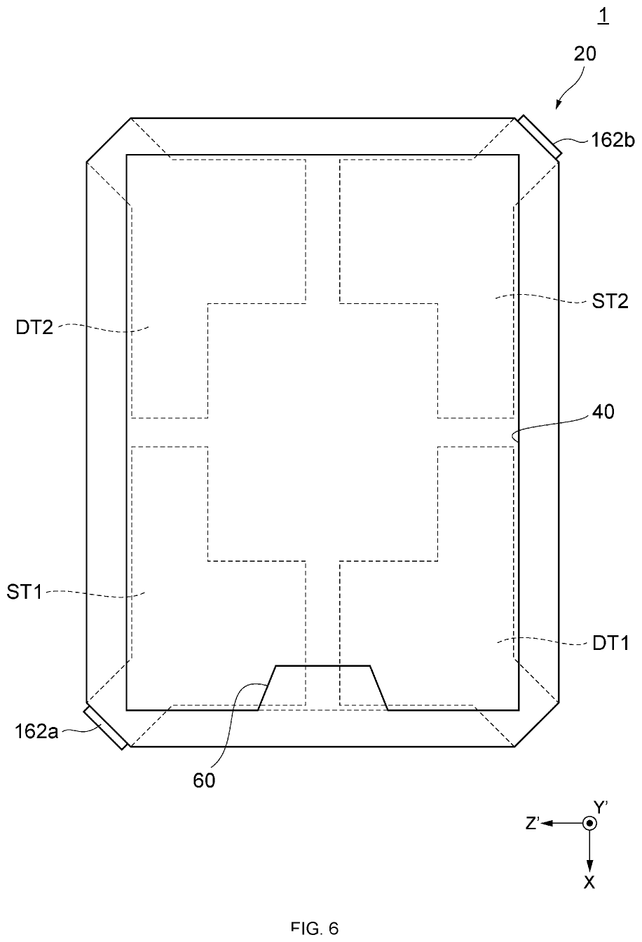

First, a configuration of a crystal vibrator according to a first embodiment will be described with reference to FIGS. 1 to 6. FIG. 1 is an exploded perspective view of the crystal vibrator according to the first embodiment. FIG. 2 is a certain sectional view taken along line II-II of the crystal vibrator described in the first embodiment. FIG. 3 is a certain sectional view taken along line III-III of the crystal vibrator described in the first embodiment. FIG. 4 is a plan view of the crystal vibrator according to the first embodiment. FIG. 5 is a plan view of a crystal vibration element according to the first embodiment. FIG. 6 is a plan view of a lower lid according to the first embodiment.

FIG. 2 is the certain sectional view of the crystal vibrator 1 in an X-Y′ plane and illustrates a sectional structure passing through a center portion of a vibration part 110 described later. FIG. 3 is the certain sectional view of the crystal vibrator 1 in a Y′-Z′ plane and illustrates a sectional structure passing through a connected part 132 of a support arm 130 described later with respect to a holding part 120.

The crystal vibrator 1 includes the crystal vibration element 10, a lower lid 20, an upper lid 30, a lower bonding part 40, an upper bonding part 50, a lower reinforcement part 60, and an upper reinforcement part 70. The lower lid 20, the crystal vibration element 10, and the upper lid 30 are arranged in this order with a gap therebetween in the Y′ axis direction. Below, the Y′ axis direction in which the lower lid 20, the crystal vibration element 10, and the upper lid 30 are stacked is referred to as a “thickness direction.” The upper lid 30 corresponds to an example of a first substrate, and the lower lid 20 corresponds to an example of a second substrate. The upper bonding part 50 corresponds to an example of a first bonding part, and the lower bonding part 40 corresponds to an example of a second bonding part. The upper reinforcement part 70 corresponds to an example of a first reinforcement part, and the lower reinforcement part 60 corresponds to an example of a second reinforcement part.

For example, the crystal vibrator 1 is used as a component of a temperature compensated crystal oscillator (TCXO), a voltage controlled crystal oscillator (VCXO), or an oven controlled crystal oscillator (OCXO).

The crystal vibration element 10 is an electro-mechanical energy conversion element that mutually converts electrical energy and mechanical energy by a piezoelectric effect. As illustrated in FIG. 1, the crystal vibration element 10 includes the vibration part 110, the holding part 120, and the support arm 130.

The vibration part 110 is excited at a predetermined frequency based on an applied alternating voltage. The vibration part 110 is held so as to be vibratable in a vibration space provided between the lower lid 20 and the upper lid 30. Main vibration of the vibration part 110 is in a thickness shear vibration mode.

As illustrated in FIG. 5, a shape of the vibration part 110 (hereinafter referred to as a “planar shape”) when the X-Z′ plane is seen in plan view (hereinafter simply referred to as “plan view”) is a rectangular shape. The vibration part 110 includes a pair of short sides 111A and 111B and a pair of long sides 111C and 111D. The pair of short sides 111A and 111B extend in the Z′ axis direction and face each other in the X axis direction. The pair of long sides 111C and 111D extend in the X axis direction and face each other in the Z′ axis direction. The short side 111A is located at an end portion of the vibration part 110 on the X-axis negative side. The short side 111B is located at an end portion of the vibration part 110 on the X-axis positive side. The long side 111C is located at an end portion of the vibration part 110 on the Z′-axis positive side. The long side 111D is located at an end portion of the vibration part 110 on the Z′-axis negative side.

Note that the main vibration of the vibration part is not limited to the thickness shear vibration mode, and may be, for example, a thickness expansion vibration mode, an area expansion vibration mode, a length vibration mode, or a flexural vibration mode. Further, the planar shape of the vibration part is not limited to a rectangular shape, and may be, for example, a square shape, a polygonal shape, a circular shape, an elliptical shape, or a combination thereof.

The holding part 120 is a portion for holding the vibration part 110. As illustrated in FIGS. 1 to 3, the holding part 120 forms, together with the lower lid 20, the upper lid 30, the lower bonding part 40, and the upper bonding part 50, the vibration space for the vibration part 110. As illustrated in FIG. 5, when viewed in plan view, the holding part 120 is disposed in a frame-shaped region surrounding the vibration part 110 such that the holding part 120 has a gap from the vibration part 110.

As illustrated in FIG. 5, the holding part 120 includes frame parts 121A, 121B, 121C, and 121D. The frame parts 121A, 121B, 121C, and 121D are each a part of a substantially rectangular frame body surrounding the vibration part 110. The frame part 121A is provided on the X-axis negative side of the vibration part 110, the frame part 121B is provided on the X-axis positive side of the vibration part 110, the frame part 121C is provided on the Z′-axis positive side of the vibration part 110, and the frame part 121D is provided on the Z′-axis negative side of the vibration part 110. The frame part 121A is provided with a gap in the X axis direction from the short side 111A of the vibration part 110 and extends parallel to the short side 111A in the Z′ axis direction. The frame part 121B is provided with a gap in the X axis direction from the short side 111B of the vibration part 110 and extends parallel to the short side 111B in the Z′ axis direction. The frame part 121C is provided with a gap in the Z′ axis direction from the long side 111C of the vibration part 110 and extends parallel to the long side 111C in the X axis direction. The frame part 121D is provided with a gap in the Z′ axis direction from the long side 111D of the vibration part 110 and extends parallel to the long side 111D in the X axis direction.

Both ends of the frame part 121C are connected to respective ones of one end of the frame part 121A and one end of the frame part 121B. Both ends of the frame part 121D are connected to respective ones of the other end of the frame part 121A and the other end of the frame part 121B. The frame part 121A and the frame part 121B face each other in the X axis direction with the vibration part 110 sandwiched therebetween. The frame part 121C and the frame part 121D face each other in the Z′ axis direction with the vibration part 110 sandwiched therebetween.

Note that the holding part only needs to be provided to at least a part of the frame-shaped region surrounding the vibration part, and is not limited to having a frame shape. The holding part may be provided, for example, in a rail shape having two parallel frame parts.

The support arm 130 supports the vibration part 110 and allows the holding part 120 to hold the vibration part 110. The support arm 130 couples the vibration part 110 and the holding part 120. As illustrated in FIG. 5, the support arm 130 couples an end portion of the vibration part 110 on the side of the short side 111B and the frame part 121B of the holding part 120. The support arm 130 extends along the X axis. A dimension of the support arm 130 in the Z′ axis direction (hereinafter referred to as “width”) is smaller than a width of the vibration part 110.

The lower lid 20 is opposed to the vibration part 110, the holding part 120, and the support arm 130 of the crystal vibration element 10 with a gap in the Y′ axis direction. The lower lid 20 is provided in a flat plate shape. As illustrated in FIG. 6, when seen in plan view, the lower lid 20 includes a pair of long sides extending in the X axis direction and facing each other in the Z′ axis direction, and a pair of short sides extending in the Z′ axis direction and facing each other in the X axis direction. Further, at each corner of the lower lid 20 when seen in plan view, the long side and the short side of the lower lid 20 are coupled by a side extending in a direction intersecting with both of the concerned long side and short side. That is, cutouts are formed at the respective four corners of the lower lid 20 in plan view.

The upper lid 30 is opposed to the vibration part 110, the holding part 120, and the support arm 130 of the crystal vibration element 10 with a gap in the Y′ axis direction on the opposite side to the lower lid 20. The upper lid 30 is provided in a flat plate shape. As illustrated in FIG. 1, when seen in plan view, the upper lid 30 includes a pair of long sides extending in the X axis direction and facing each other in the Z′ axis direction, and a pair of short sides extending in the Z′ axis direction and facing each other in the X axis direction. A planar shape of the upper lid 30 is a rectangular shape.

The lower bonding part 40 and the upper bonding part 50 are each provided in a frame shape along the holding part 120 of the crystal vibration element 10. The lower bonding part 40 bonds the holding part 120 of the crystal vibration element 10 and an end portion of the lower lid 20. The upper bonding part 50 bonds the holding part 120 of the crystal vibration element 10 and an end portion of the upper lid 30. The lower bonding part 40 and the upper bonding part 50 are made of, for example, an organic adhesive including an epoxy-based, vinyl-based, acrylic-based, urethane-based, or silicone-based resin.

A material for the lower bonding part and the upper bonding part is not limited to an organic adhesive, and may be an inorganic adhesive such as a silicon-based adhesive including water glass, or a calcium-based adhesive including cement. The material for the lower bonding part and the upper bonding part may be low-melting-point glass (for example, lead-borate based or tin-phosphate based glass). The material for the lower bonding part and the upper bonding part may be gold (Au), tin (Sn), copper (Cu), titanium (Ti), aluminum (Al), germanium (Ge), silicon (Si), or a eutectic alloy containing at least one of these. Note that from the perspectives of suppressing raw material costs and saving processes and energy in manufacturing, the material for the lower bonding part and the upper bonding part is desirably an adhesive rather than a metallic material such as a eutectic alloy.

The lower reinforcement part 60 and the upper reinforcement part 70 cover at least a part of the support arm 130 and reinforce the mechanical strength of the support arm 130. The lower reinforcement part 60 restricts a downward displacement of the support arm 130, that is, a displacement toward the lower lid 20. As illustrated in FIGS. 2 and 3, the lower reinforcement part 60 couples the support arm 130 and the lower lid 20. The lower reinforcement part 60 is provided in a pillar shape extending from the support arm 130 toward the lower lid 20 in the Y′ axis direction. The upper reinforcement part 70 restricts an upward displacement of the support arm 130, that is, a displacement toward the upper lid 30. As illustrated in FIGS. 2 and 3, the upper reinforcement part 70 couples the support arm 130 and the upper lid 30. The upper reinforcement part 70 is provided in a pillar shape extending from the support arm 130 toward the upper lid 30 in the Y′ axis direction.

An elastic modulus of the lower reinforcement part 60 is equal to an elastic modulus of the upper reinforcement part 70. The elastic modulus of the lower reinforcement part 60 and the upper reinforcement part 70 is smaller than an elastic modulus of the crystal substrate 11 described later and is desirably smaller than an elastic modulus of the lower bonding part 40 and the upper bonding part 50. A material for the lower reinforcement part 60 is, for example, the same as a material for the upper reinforcement part 70. The material for the lower reinforcement part 60 and the upper reinforcement part 70 is, for example, the same as the material for the lower bonding part 40 and the upper bonding part 50. The lower reinforcement part 60 and the upper reinforcement part 70 are made of, for example, an organic adhesive including an epoxy-based, vinyl-based, acrylic-based, urethane-based, or silicone-based resin.

Note that the material for the lower reinforcement part and the upper reinforcement part is not limited to the above. The material for the lower reinforcement part and the upper reinforcement part may be different from the material for the lower bonding part and the upper bonding part. Further, the material for the lower reinforcement part may be different from the material for the upper reinforcement part.

Next, detailed configurations of the crystal vibration element 10, the lower lid 20, the upper lid 30, the lower reinforcement part 60, and the upper reinforcement part 70 will be described.

The crystal vibration element 10 includes the crystal substrate 11, a first excitation electrode 14a, a second excitation electrode 14b, a first extraction electrode 15a, a second extraction electrode 15b, a first connection electrode 16a, and a second connection electrode 16b.

The crystal substrate 11 is a type of piezoelectric substrate made of a piezoelectric material that vibrates in accordance with an applied voltage. The crystal substrate 11 extends continuously across the vibration part 110, the holding part 120, and the support arm 130. In the X-Z′ plane direction, the crystal substrate 11 extends over substantially the entire region of each of the vibration part 110, the holding part 120, and the support arm 130. The crystal substrate 11 is a flake-shaped quartz crystal having a main surface in the X-Z′ plane.

The crystal substrate 11 is, for example, an AT-cut crystal substrate. That is, the counterclockwise rotation angle θ of the Z′ axis and the Y′ axis from the Z axis and the Y axis, respectively, when seen from the X-axis positive side is 35 degrees 15 minutes±1 minute 30 seconds. The crystal vibration element 10 using the AT-cut crystal substrate 11 has high frequency stability over a wide temperature range.

Note that the cut-angles of the crystal substrate are not limited to the above. The rotation angle of the Y′ axis and the Z′ axis in the AT-cut crystal substrate 11 may be tilted within a range of −5 degrees or more or +15 degrees or less from 35 degrees 15 minutes. Further, cuts other than the AT-cut, for example, BT-cut, GT-cut, SC-cut, or the like may be applied to the cut-angles of the crystal substrate.

A planar shape of the crystal substrate 11 at the vibration part 110 is a rectangular shape including long sides in the X axis direction and short sides in the Z′ axis direction. As illustrated in FIG. 2, at the vibration part 110, the crystal substrate 11 includes an upper surface 11A provided closer to the upper lid 30 and a lower surface 11B provided closer to the lower lid 20. The upper surface 11A and the lower surface 11B face each other in the Y′ axis direction of the crystal substrate 11. The upper surface 11A corresponds to an example of a first main surface of the crystal substrate 11 at the vibration part 110. The lower surface 11B corresponds to an example of a second main surface of the crystal substrate 11 at the vibration part 110.

As illustrated in FIG. 4, in plan view, the vibration part 110 includes a center portion 117 and a peripheral portion 118. The center portion 117 is provided at a center of the vibration part 110, and the peripheral portion 118 is provided around the center portion 117. In plan view, the peripheral portion 118 surrounds the center portion 117. A thickness of the crystal substrate 11 at the center portion 117 is substantially equal to a thickness of the crystal substrate 11 at the peripheral portion 118. That is, at the vibration part 110, the crystal substrate 11 has a flat plate shape with a uniform thickness.

Note that the planar shape of the vibration part of the crystal substrate is not limited to the above. For example, the planar shape of the vibration part of the crystal substrate may be a rectangular shape including long sides extending in the Z′ axis direction and short sides extending in the X axis direction, or a rectangular shape including short sides extending in the Z′ axis direction and long sides extending in the X axis direction. The planar shape of the vibration part of the crystal substrate may be a polygonal shape, a circular shape, an elliptical shape, or a combination thereof. Further, the vibration part of the crystal substrate is not limited to having a flat plate shape, and the thickness at the center portion and the thickness at the peripheral portion may be different. For example, the vibration part of the crystal substrate may have a mesa-type structure in which at least one of the upper surface and the lower surface is provided to be projected at the center portion, or an inverted-mesa-type structure in which at least one of the upper surface and the lower surface is provided to be recessed at the center portion. The vibration part of the crystal substrate may have a convex structure in which an amount of change in thickness changes continuously from the peripheral portion to the center portion, or a beveled structure in which an amount of change in thickness changes discontinuously.

As illustrated in FIG. 5, a planar shape of the crystal substrate 11 at the holding part 120 is a rectangular-frame shape including long sides in the X axis direction and short sides in the Z′ axis direction. As illustrated in FIG. 2, at the holding part 120, the crystal substrate 11 has an upper surface 12A provided closer to the upper lid 30 and a lower surface 12B provided closer to the lower lid 20. The upper surface 12A corresponds to an example of the first main surface of the crystal substrate 11 at the holding part 120. The lower surface 12B corresponds to an example of the second main surface of the crystal substrate 11 at the holding part 120.

As illustrated in FIG. 2, a thickness of the crystal substrate 11 at the holding part 120 is greater than the thickness of the crystal substrate 11 at the vibration part 110. The thicknesses of the crystal substrate 11 at the respective ones of the frame parts 121A, 121B, 121C, and 121D are substantially equal to each other. However, the thickness of the crystal substrate at the holding part may be equal to the thickness of the crystal substrate 11 at the vibration part, or may be smaller than the thickness of the crystal substrate 11 at the vibration part.

As illustrated in FIG. 5, a planar shape of the crystal substrate 11 at the support arm 130 is a rectangular-frame shape. As illustrated in FIG. 3, at the support arm 130, the crystal substrate 11 includes an upper surface 13A, a lower surface 13B, and side surfaces 13C and 13D. The upper surface 13A is opposed to the upper lid 30, and the lower surface 13B is opposed to the lower lid 20. The side surface 13C couples end portions of the respective ones of the upper surface 13A and the lower surface 13B on the Z′-axis positive side and is opposed to the frame part 121C. The side surface 13D couples end portions of the respective ones of the upper surface 13A and the lower surface 13B on the Z′-axis negative side and is opposed to the frame part 121D. The upper surface 13A corresponds to an example of the first main surface of the crystal substrate 11 at the support arm 130. The lower surface 13B corresponds to an example of the second main surface of the crystal substrate 11 at the support arm 130. The side surface 13C corresponds to an example of a first side surface of the crystal substrate 11 at the support arm 130. The side surface 13D corresponds to an example of a second side surface of the crystal substrate 11 at the support arm 130.

Each of the side surfaces 13C and 13D includes, for example, one flat surface extending along the X-Y′ plane, but is not limited thereto. The side surface of the support arm may include a plurality of surfaces including an inclined surface extending in a direction intersecting the X-Y′ plane, or may include a curved surface.

As illustrated in FIG. 2, the support arm 130 includes a connected part 131 with respect to the vibration part 110 and the connected part 132 with respect to the holding part 120.

The crystal substrate 11 at the support arm 130 is provided in a flat plate shape with a uniform thickness. As illustrated in FIG. 2, the thickness of the crystal substrate 11 at the support arm 130 is substantially equal to the thickness of the crystal substrate 11 at the vibration part 110, and is smaller than the thickness of the crystal substrate 11 at the holding part 120. That is, the upper surface 11A and the upper surface 13A are provided continuously in the X-Z′ plane direction, and the lower surface 11B and the lower surface 13B are provided continuously in the X-Z′ plane direction. Further, a step is provided between the upper surface 13A and the upper surface 12A, and a step is provided between the lower surface 13B and the lower surface 12B.

Note that the thickness of the crystal substrate at the support arm is not limited to the above. At the support arm, the thickness of the crystal substrate may change. For example, a projection or a recess may be provided to the upper surface and the lower surface of the crystal substrate at the support arm. When the crystal substrate at the support arm includes such a projection or a recess, wet spreading of the adhesive forming the lower reinforcement part and the upper reinforcement part can be restricted by the projection or the recess. That is, the shape and dimensions of the lower reinforcement part and the upper reinforcement part can be controlled by the shape of the projection or the recess of the crystal substrate at the support arm.

Further, the thickness of the crystal substrate at the support arm may be smaller than the thickness of the crystal substrate at the vibration part, or may be equivalent to the thickness of the crystal substrate at the holding part. Further, the thickness of the crystal substrate at the support arm may be larger than the thickness of the crystal substrate at the vibration part and smaller than the thickness of the crystal substrate at the holding part.

The first excitation electrode 14a and the second excitation electrode 14b apply an alternating voltage to the crystal substrate 11 at the vibration part 110 to excite the vibration part 110. The first excitation electrode 14a and the second excitation electrode 14b are disposed on the center portion 117 of the vibration part 110. As illustrated in FIG. 2, the first excitation electrode 14a is disposed on the upper surface 11A of the crystal substrate 11 at the vibration part 110, and the second excitation electrode 14b is disposed on the lower surface 11B of the crystal substrate 11 at the vibration part 110. The first excitation electrode 14a and the second excitation electrode 14b face each other in the Y′ axis direction with the crystal substrate 11 sandwiched therebetween. As illustrated in FIG. 5, when viewed in plan view, each of the first excitation electrode 14a and the second excitation electrode 14b has a rectangular shape, and they are arranged so as to substantially entirely overlap each other.

Note that a planar shape of each of the first excitation electrode and the second excitation electrode is not limited to a rectangular shape. The planar shape of each of the first excitation electrode and the second excitation electrode may be a polygonal shape, a circular shape, an elliptical shape, or a combination thereof. Further, the planar shape of the first excitation electrode is not limited to being the same as that of the second excitation electrode, and the first excitation electrode and the second excitation electrode may have different planar shapes. When seen in plan view, an area of the first excitation electrode is, for example, substantially equal to an area of the second excitation electrode, but may be different from the area of the second excitation electrode.

The first extraction electrode 15a electrically connects the first excitation electrode 14a and the first connection electrode 16a. As illustrated in FIG. 1, the first extraction electrode 15a extending from the first excitation electrode 14a extends over the vibration part 110, the upper surfaces of the support arm 130 and the frame part 121B of the holding part 120, and the side surface of the holding part 120, and is electrically connected to the first connection electrode 16a provided to the lower surface of the holding part 120. The second extraction electrode 15b extending from the second excitation electrode 14b extends over the vibration part 110, the lower surface, the side surface, and the upper surface of the support arm 130, the upper surfaces of the frame parts 121B and 121D of the holding part 120, and the side surface of the holding part 120, and is electrically connected to the second connection electrode 16b provided to the lower surface of the holding part 120.

The first connection electrode 16a electrically connects the first excitation electrode 14a to an external terminal, and the second connection electrode 16b electrically connects the second excitation electrode 14b to an external terminal. As illustrated in FIG. 1, the first connection electrode 16a is provided to the lower surface 12B of the crystal substrate 11 at a corner of the holding part 120. At the corner, the frame part 121B and the frame part 121C are connected. The second connection electrode 16b is provided to the lower surface 12B of the crystal substrate 11 at a corner of the holding part 120. At the corner, the frame part 121A and the frame part 121D are connected.

The first excitation electrode 14a, the first extraction electrode 15a, and the first connection electrode 16a are provided integrally. The same applies to the second excitation electrode 14b, the second extraction electrode 15b, and the second connection electrode 16b. These electrodes of the crystal vibration element 10 have, for example, a single-layer structure including an aluminum layer, but are not limited thereto. The electrodes of the crystal vibration element may have a multilayer structure including an underlying layer and a surface layer stacked in this order. For example, the underlying layer is a chromium (Cr) layer with favorable adhesion to the crystal substrate, and the surface layer is a gold (Au) layer with favorable chemical stability. The electrodes of the crystal vibration element may include silver (Ag), copper (Cu), titanium (Ti), molybdenum (Mo), or an aluminum-copper alloy (AlCu).

The lower lid 20 includes a crystal substrate 21, power supply terminals ST1 and ST2, and dummy terminals DT1 and DT2. The crystal substrate 21 is a substrate having a flat plate shape and overlapping substantially the entirety of the crystal vibration element 10 in plan view. The crystal substrate 21 is made of a quartz crystal with the same cut-angles as those of the crystal substrate 11 of the crystal vibration element 10. Accordingly, it is possible to reduce thermal stress caused by difference in thermal expansion coefficient and difference in direction of thermal expansion and contraction between the crystal vibration element 10 and the lower lid 20. As a result, frequency fluctuation of the crystal vibration element 10 is suppressed. The crystal substrate 21 includes an upper surface 21A provided closer to the crystal vibration element 10 and a lower surface 21B provided on the opposite side to the upper surface 21A. When seen in plan view, the crystal substrate 21 includes long sides extending in the X axis direction and short sides extending in the Z′ axis direction. A cutout is formed at each corner where the short side and the long side of the crystal substrate 21 are connected. An area of the crystal substrate 21 in plan view is smaller than an area of a crystal substrate 31, which will be described later, in plan view by an amount of the cutouts. A shape of a side surface formed by the cutout at the corner of the crystal substrate 21 is, for example, flat. However, the shape of the side surface formed by the cutout at the corner of the crystal substrate 21 is not limited thereto, and may be a curved surface that is part of a side surface of a cylinder or a prism.

The power supply terminals ST1 and ST2 and the dummy terminals DT1 and DT2 are provided to the lower surface 21B of the crystal substrate 21. The power supply terminals ST1 and ST2 and the dummy terminals DT1 and DT2 correspond to examples of external terminals of the crystal vibrator 1. The power supply terminals ST1 and ST2 are for giving a drive signal (drive voltage) to the crystal vibrator 1. The power supply terminal ST1 is electrically connected to the first connection electrode 16a via a side surface electrode 162a provided to the cutout at the corner of the crystal substrate 21 and an outer side surface of the lower bonding part 40. The power supply terminal ST2 is electrically connected to the second connection electrode 16b via a side surface electrode 162b provided to the cutout at the corner of the crystal substrate 21 and the outer side surface of the lower bonding part 40. The dummy terminals DT1 and DT2 are for balancing electrical characteristics such as electrostatic capacity and balancing mechanical strength with the power supply terminals ST1 and ST2. The dummy terminals DT1 and DT2 are so-called floating electrodes not electrically connected to the crystal vibration element 10.

Note that at least one of the dummy terminals DT1 and DT2 may be a ground electrode that electrically grounds a part of the crystal vibrator 1.

The upper lid 30 includes the crystal substrate 31. The crystal substrate 31 is a substrate having a flat plate shape and overlapping substantially the entirety of the crystal vibration element 10 in plan view. The crystal substrate 31 is made of a quartz crystal with the same cut-angles as those of the crystal substrate 11 of the crystal vibration element 10. Accordingly, it is possible to reduce thermal stress caused by difference in thermal expansion coefficient and difference in direction of thermal expansion and contraction between the crystal vibration element 10 and the upper lid 30. As a result, frequency fluctuation of the crystal vibration element 10 is suppressed. The crystal substrate 31 includes a lower surface 31B provided closer to the crystal vibration element 10 and an upper surface 31A provided on the opposite side to the lower surface 31B. When seen in plan view, the crystal substrate 31 has a rectangular shape including long sides extending in the X axis direction and short sides extending in the Z′ axis direction.

Note that the cut-angles of the crystal substrates 21 and 31 of the respective ones of the lower lid 20 and the upper lid 30 are not particularly limited, and may be different from the cut-angles of the crystal substrate 11 of the crystal vibration element 10. Further, each of the lower lid 20 and the upper lid 30 may include, instead of the crystal substrate 21 or 31, a glass substrate, a silicon substrate, a ceramic substrate, a metal substrate, a composite substrate combining these, or the like.

As illustrated in FIGS. 3 and 4, the lower reinforcement part 60 is provided continuously from an end portion of the lower surface 13B on the side of the side surface 13C to an end portion of the lower surface 13B on the side of the side surface 13D, at the connected part 132 of the support arm 130 with respect to the holding part 120. The lower reinforcement part 60 is provided continuously from the lower surface 13B to the side surface 13C at the connected part 132 and covers a corner where the lower surface 13B and the side surface 13C are connected. Further, the lower reinforcement part 60 is provided continuously from the lower surface 13B to the side surface 13D at the connected part 132 and covers a corner where the lower surface 13B and the side surface 13D are connected. The lower reinforcement part 60 is connected to the lower bonding part 40. As illustrated in FIG. 4, when seen in plan view, the lower reinforcement part 60 extends along the support arm 130 from a part of the lower bonding part 40 toward the vibration part 110. The part of the lower bonding part 40 is provided along the frame part 121B. A material for the lower reinforcement part 60 is, for example, the same as the material for the lower bonding part 40. In such a case, the lower reinforcement part 60 and the lower bonding part 40 can be simultaneously formed by the same process.

As illustrated in FIGS. 3 and 4, the upper reinforcement part 70 is provided continuously from an end portion of the upper surface 13A on the side of the side surface 13C to an end portion of the upper surface 13A on the side of the side surface 13D, at the connected part 132 of the support arm 130 with respect to the holding part 120. The upper reinforcement part 70 is provided continuously from the upper surface 13A to the side surface 13C at the connected part 132 and covers a corner where the upper surface 13A and the side surface 13C are connected. Further, the upper reinforcement part 70 is provided continuously from the upper surface 13A to the side surface 13D at the connected part 132 and covers a corner where the upper surface 13A and the side surface 13D are connected. The upper reinforcement part 70 is connected to the upper bonding part 50. As illustrated in FIG. 4, when seen in plan view, the upper reinforcement part 70 extends along the support arm 130 from a part of the upper bonding part 50 toward the vibration part 110. The part of the upper bonding part 50 is provided along the frame part 121B. A material for the upper reinforcement part 70 is, for example, the same as the material for the upper bonding part 50. In such a case, the upper reinforcement part 70 and the upper bonding part 50 can be simultaneously formed by the same process.

As illustrated in FIG. 3, the lower reinforcement part 60 and the upper reinforcement part 70 are connected to each other at the connected part 132 of the support arm 130 with respect to the holding part 120. At the connected part 132, the support arm 130 is surrounded by the lower reinforcement part 60 and the upper reinforcement part 70.

Note that the region where the lower reinforcement part 60 and the upper reinforcement part 70 are provided is not limited to the above. The lower reinforcement part 60 may be provided only to the lower surface 13B among the lower surface 13B and the side surfaces 13C and 13D of the support arm 130. The lower reinforcement part 60 may be provided to one of the side surfaces 13C and 13D of the support arm 130 and separated from the other side surface. The lower reinforcement part 60 may be provided to the entire surface of the lower surface 13B of the support arm 130, or may be provided to the entire surface of one or both of the side surfaces 13C and 13D of the support arm 130. The lower reinforcement part 60 may be separated from the end portion of the lower surface 13B of the support arm 130 on the side of the side surface 13C, that is, the corner where the lower surface 13B and the side surface 13C are connected. The lower reinforcement part 60 may be separated from the end portion of the lower surface 13B of the support arm 130 on the side of the side surface 13D, that is, the corner where the lower surface 13B and the side surface 13D are connected. The lower reinforcement part 60 may be separated from the connected part 132 of the support arm 130 with respect to the holding part 120. The lower reinforcement part 60 may extend to the connected part 131 of the support arm 130 with respect to the vibration part 110. From the perspective of suppressing degradation of vibration characteristics of the crystal vibration element 10, the lower reinforcement part 60 is desirably separated from the vibration part 110, but the lower reinforcement part 60 may extend from the support arm 130 to the peripheral portion 118 of the vibration part 110 as long as it is separated from the center portion 117 of the vibration part 110. The same applies to the upper reinforcement part 70.

Note that the lower reinforcement part 60 and the upper reinforcement part 70 are provided, for example, in a substantially vertically-symmetrical manner, but are not limited thereto. A planar shape and planar dimensions of the lower reinforcement part 60 may be different from a planar shape and planar dimensions of the upper reinforcement part 70. A sectional shape and sectional dimensions of the lower reinforcement part 60 along the X-Y′ plane may be different from a sectional shape and sectional dimensions of the upper reinforcement part 70 along the X-Y′ plane. A sectional shape and sectional dimensions of the lower reinforcement part 60 along the Y′-Z′ plane may be different from a sectional shape and sectional dimensions of the upper reinforcement part 70 along the Y′-Z′ plane. For example, one of the lower reinforcement part 60 and the upper reinforcement part 70 may extend to the connected part 132 of the support arm 130 with respect to the holding part 120, and the other reinforcement part may be separated from the connected part 132. Further, one of the lower reinforcement part 60 and the upper reinforcement part 70 may extend to the connected part 131 of the support arm 130 with respect to the vibration part 110, and the other reinforcement part may be separated from the connected part 131.

Note that the lower reinforcement part 60 and the upper reinforcement part 70 are, for example, connected to each other, but are not limited thereto. The lower reinforcement part 60 and the upper reinforcement part 70 may be separated from each other.

Note that one of the lower reinforcement part 60 and the upper reinforcement part 70 may be omitted. In a case in which the lower reinforcement part 60 is omitted, the upper reinforcement part 70 may extend to the lower surface 13B of the support arm 130. In a case in which the upper reinforcement part 70 is omitted, the lower reinforcement part 60 may extend to the upper surface 13A of the support arm 130.

Note that the lower reinforcement part 60 is connected to the part of the lower bonding part 40 provided along the frame part 121B, but is not limited thereto. Similarly, the upper reinforcement part 70 is connected to the part of the upper bonding part 50 provided along the frame part 121B, but is not limited thereto. For example, the lower reinforcement part 60 may be separated from the lower bonding part 40, and the upper reinforcement part 70 may be separated from the upper bonding part 50. Further, the lower reinforcement part 60 may be connected to at least one of a part of the lower bonding part 40 provided along the frame part 121C and a part of the lower bonding part 40 provided along the frame part 121D. The upper reinforcement part 70 may be connected to at least one of a part of the upper bonding part 50 provided along the frame part 121C and a part of the upper bonding part 50 provided along the frame part 121D.

As described above, as a mode of this embodiment, the crystal vibrator 1 includes the reinforcement part 60, 70 covering at least a part of the support arm 130.

Accordingly, the mechanical strength of the support arm 130 is reinforced by the reinforcement part 60, 70. In addition, excessive displacement of the support arm 130 is restricted by the reinforcement part 60, 70. Upon excessive displacement of the vibration part 110 due to impact such as from a fall, reinforcing the support arm 130 where external stress is easily concentrated can suppress damage to the crystal vibration element 10. Therefore, the crystal vibrator 1 can have improved reliability.

As the mode described above, the reinforcement part 60, 70 includes the lower reinforcement part 60 connecting the support arm 130 and the lower lid 20, and the upper reinforcement part 70 connecting the support arm 130 and the upper lid 30.

Accordingly, as compared with a configuration in which only one of the lower reinforcement part 60 and the upper reinforcement part 70 is provided, the mechanical strength of the support arm 130 can be more effectively reinforced. In addition, displacement of the support arm 130 toward the lower lid 20 is restricted by the lower reinforcement part 60, and displacement of the support arm 130 toward the upper lid 30 is restricted by the upper reinforcement part 70. Thereby, excessive displacement of the support arm 130 toward both the lower lid 20 and the upper lid 30 can be restricted. Therefore, damage to the crystal vibration element 10 can be more effectively suppressed.

As the mode described above, the lower reinforcement part 60 is provided from the end portion of the lower surface 13B of the support arm 130 on the side of the side surface 13C to the end portion of the lower surface 13B on the side of the side surface 13D, and the upper reinforcement part 70 is provided from the end portion of the upper surface 13A of the support arm 130 on the side of the side surface 13C to the end portion of the upper surface 13A on the side of the side surface 13D.

Accordingly, the support arm 130 is reinforced entirely in the width direction, and thereby an excessive displacement of the support arm 130 toward the lower lid 20 or the upper lid 30 can be further restricted. In addition, a displacement of the support arm 130 in a torsion direction with the X axis as a rotation axis can be restricted. Therefore, damage to the crystal vibration element 10 can be more effectively suppressed.

As the mode described above, the lower reinforcement part 60 and the upper reinforcement part 70 cover the corners of the support arm 130 at the connected part 132 with respect to the holding part 120.

Accordingly, the corners at the connected part 132, where external stress is particularly concentrated, are reinforced by the reinforcement parts 60 and 70. Therefore, damage to the crystal vibration element 10 can be more effectively suppressed.

As the mode described above, the material for the lower reinforcement part 60 is the same as the material for the lower bonding part 40, and the material for the upper reinforcement part 70 is the same as the material for the upper bonding part 50.

Accordingly, in the step of forming the lower bonding part 40, the lower reinforcement part 60 can be formed simultaneously, and in the step of forming the upper bonding part 50, the upper reinforcement part 70 can be formed simultaneously. Therefore, manufacturing steps can be simplified as compared with a configuration in which the materials for the lower reinforcement part 60 and the lower bonding part 40 are different from each other and the materials for the upper reinforcement part 70 and the upper bonding part 50 are different from each other.

Below, other embodiments will be described. Note that configurations the same as or similar to those described in the first embodiment are denoted by the same or similar reference characters, and description thereof is omitted as appropriate. Further, similar operation and effects attributed to similar configurations will not be described one by one.

### Second Embodiment

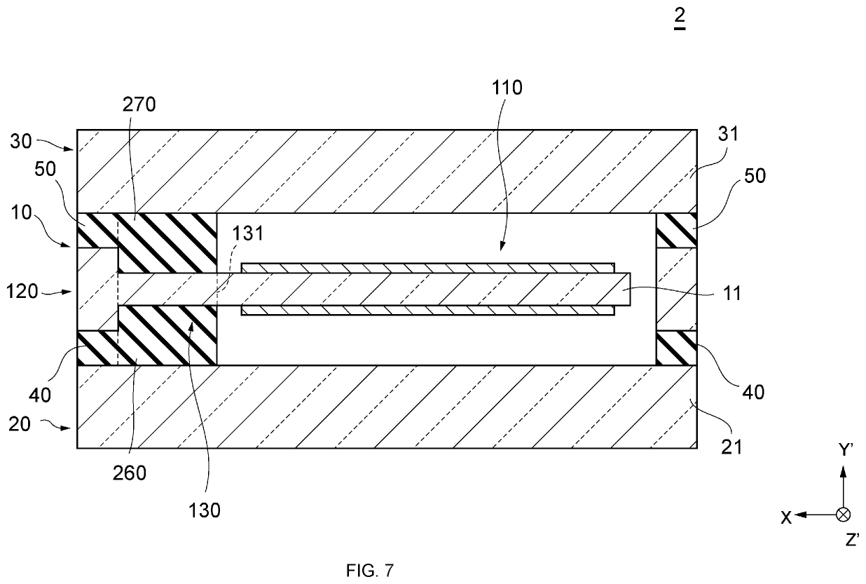

Next, a configuration of a crystal vibrator 2 according to a second embodiment will be described with reference to FIG. 7. FIG. 7 is a certain sectional view of the crystal vibrator according to the second embodiment.

In the crystal vibrator 2, a lower reinforcement part 260 and an upper reinforcement part 270 extend to the connected part 131 of the support arm 130 with respect to the vibration part 110.

Accordingly, the support arm 130 is reinforced more strongly, and thereby damage to the crystal vibration element 10 can be more effectively suppressed.

### Third Embodiment

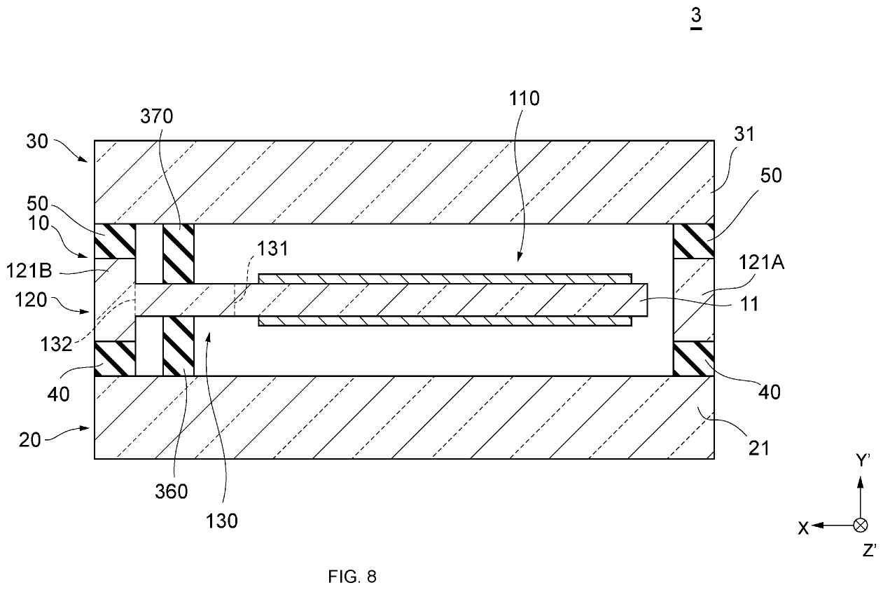

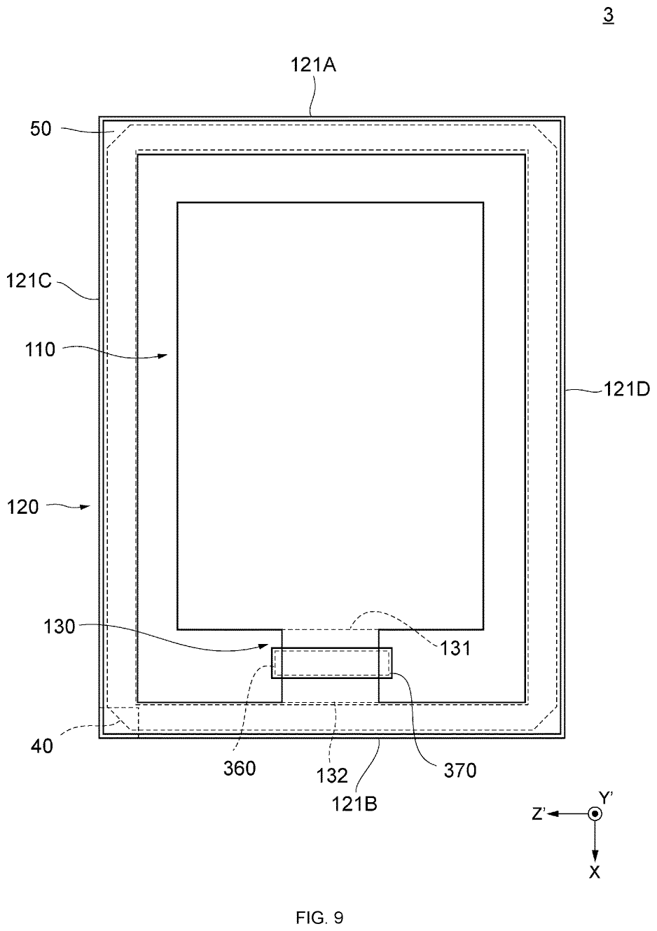

Next, a configuration of a crystal vibrator 3 according to a third embodiment will be described with reference to FIGS. 8 and 9. FIG. 8 is a certain sectional view of the crystal vibrator according to the third embodiment. FIG. 9 is a plan view of the crystal vibrator according to the third embodiment.

In the crystal vibrator 3, a lower reinforcement part 360 is separated from the lower bonding part 40, and an upper reinforcement part 370 is separated from the upper bonding part 50. The lower reinforcement part 360 is provided in an island shape away from any of the parts of the lower bonding part 40 provided along the respective ones of the frame parts 121A to 121D, in a region surrounded by the lower bonding part 40. The upper reinforcement part 370 is provided in an island shape away from any of the parts of the upper bonding part 50 provided along the respective ones of the frame parts 121A to 121D, in a region surrounded by the upper bonding part 50.

### Fourth Embodiment

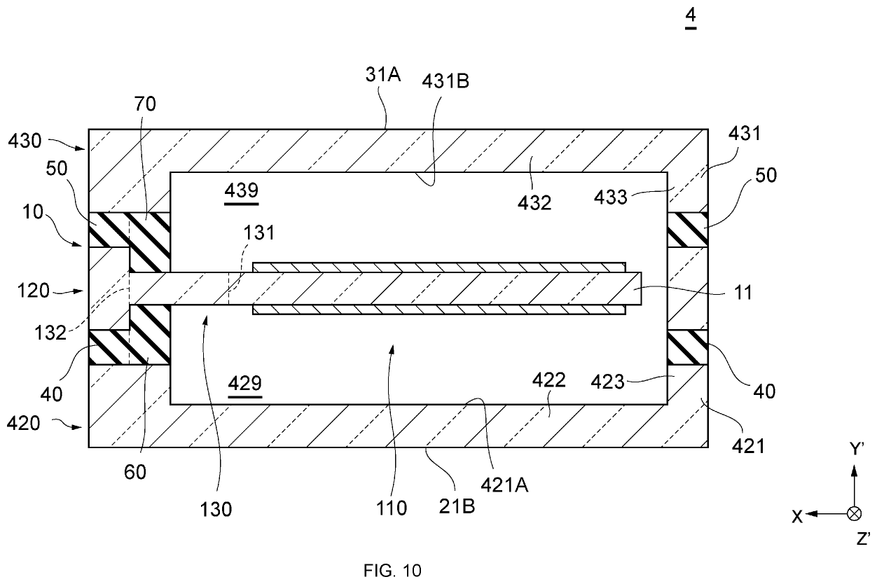

Next, a configuration of a crystal vibrator 4 according to a fourth embodiment will be described with reference to FIG. 10. FIG. 10 is a certain sectional view of the crystal vibrator according to the fourth embodiment.

In the crystal vibrator 4, an upper surface 421A of a crystal substrate 421 of a lower lid 420 is provided to be recessed. The crystal substrate 421 includes a bottom wall part 422 in a flat plate shape and a side wall part 423 extending from an outer edge portion of the bottom wall part 422 toward the holding part 120. The bottom wall part 422 and the side wall part 423 form a cavity 429. A lower surface 431B of a crystal substrate 431 of an upper lid 430 is provided to be recessed. The crystal substrate 431 includes a bottom wall part 432 in a flat plate shape and a side wall part 433 extending from an outer edge portion of the bottom wall part 432 toward the holding part 120. The bottom wall part 432 and the side wall part 433 form a cavity 439. In plan view, the bottom wall parts 422 and 432 overlap the entirety of the vibration part 110, and the side wall parts 423 and 433 surround the vibration part 110 with a gap. That is, the lower lid 420 is provided with the cavity 429 larger than the vibration part 110 in plan view, and the upper lid 430 is provided with the cavity 439 larger than the vibration part 110 in plan view. The cavity 439 corresponds to an example of a first cavity, and the cavity 429 corresponds to an example of a second cavity.

Accordingly, the vibration space for the vibration part 110 is expanded. Therefore, even if the crystal vibrator 4 is miniaturized, the vibration space for the vibration part 110 can be secured.

### Fifth Embodiment

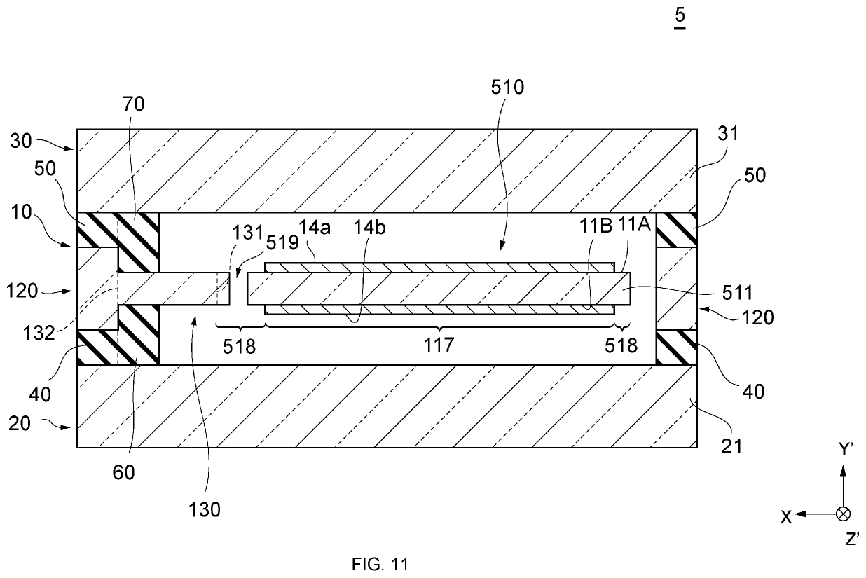

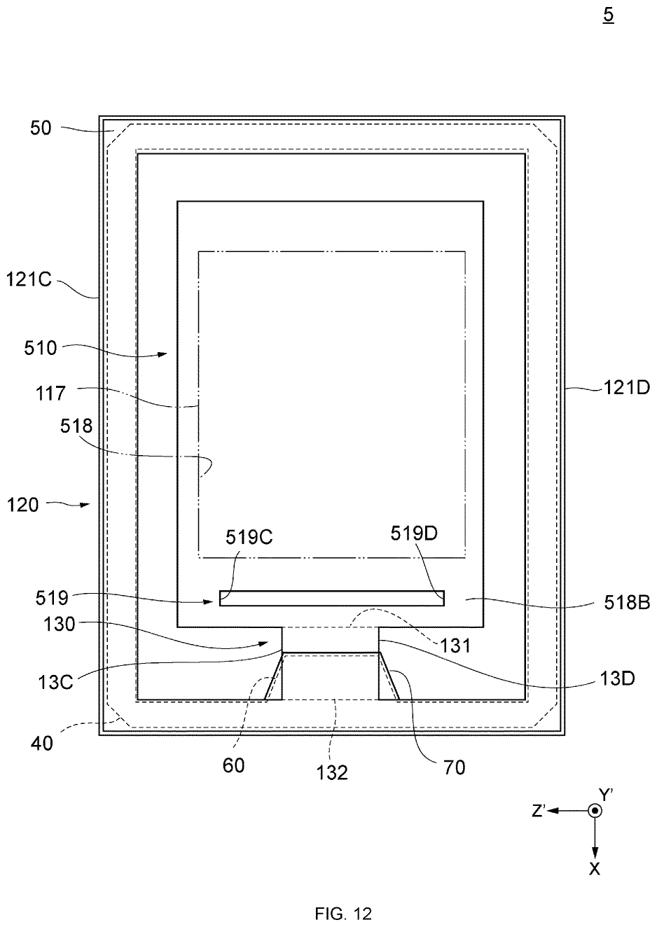

Next, a configuration of the crystal vibrator 3 according to a fifth embodiment will be described with reference to FIGS. 11 and 12. FIG. 11 is a certain sectional view of the crystal vibrator according to the fifth embodiment. FIG. 12 is a plan view of the crystal vibrator according to the fifth embodiment.

In a crystal vibrator 5, an opening 519 opening both on the upper surface 11A and on the lower surface 11B of a crystal substrate 511 is provided to a peripheral portion 518B. The peripheral portion 518B is a part of a peripheral portion 518 of a vibration part 510. The part is located between the center portion 117 and the support arm 130. The opening 519 is provided in a slot shape extending longitudinally in the Z′ axis direction. The opening 519 penetrates the crystal substrate 511 in the thickness direction. A width of the opening 519 is larger than the width of the support arm 130.

In plan view, the opening 519 includes inner side surfaces 519C and 519D. The inner side surface 519C constitutes an end portion of the opening 519 closer to the frame part 121C. The inner side surface 519D constitutes an end portion of the opening 519 closer to the frame part 121D. The side surfaces 13C and 13D of the support arm 130 are located toward the inner side surface 519D of the opening 519 with respect to the inner side surface 519C of the opening 519. Further, the side surfaces 13C and 13D of the support arm 130 are located toward the inner side surface 519C of the opening 519 with respect to the inner side surface 519D of the opening 519. In plan view, a center portion of the opening 519 and a center portion of the support arm 130 are aligned in the X axis direction. The opening 519 suppresses vibration leakage from the vibration part 510. In addition, propagation of external stress to the center portion 117 is suppressed.

In the example illustrated in FIGS. 11 and 12, the lower reinforcement part 60 and the upper reinforcement part 70 are separated from the connected part 131 of the support arm 130 with respect to the vibration part 510. However, in this embodiment, external stress tends to be concentrated at the corners at the connected part 131. Thereby, the lower reinforcement part 60 and the upper reinforcement part 70 desirably extend to the connected part 131, and further desirably cover the corners at the connected part 131.

### Sixth Embodiment

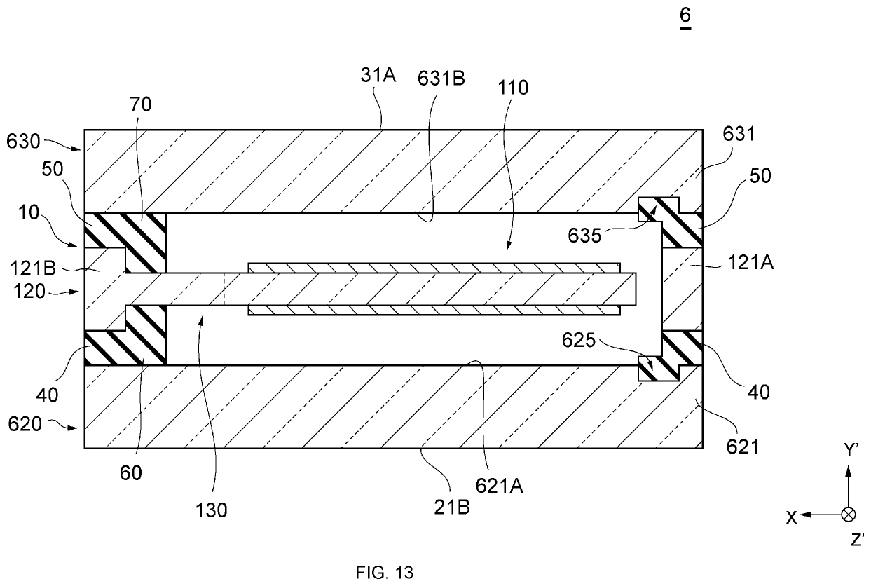

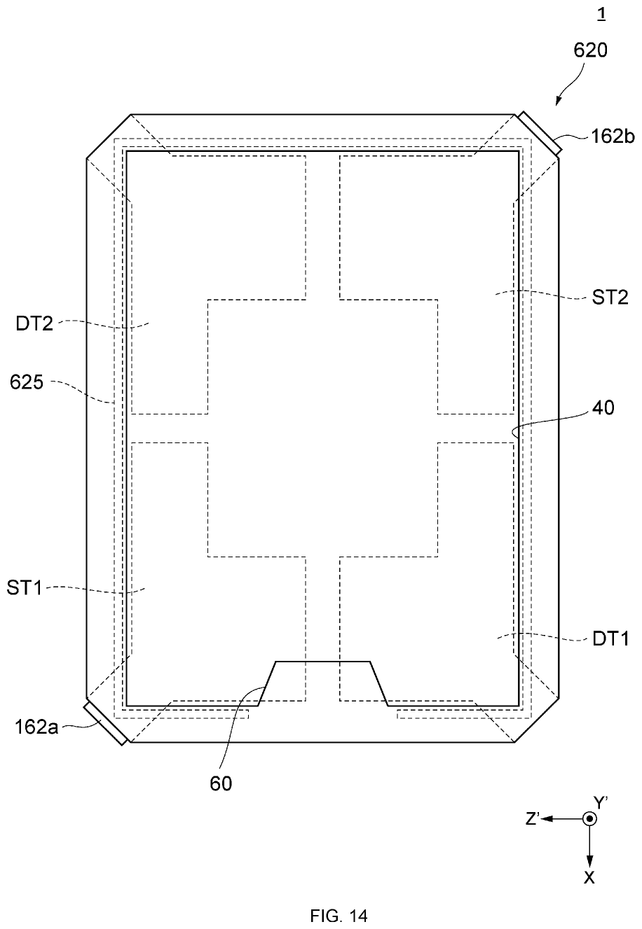

Next, a configuration of a crystal vibrator 6 according to a sixth embodiment will be described with reference to FIGS. 13 and 14. FIG. 13 is a certain sectional view of the crystal vibrator according to the sixth embodiment. FIG. 14 is a plan view of the crystal vibrator according to the sixth embodiment.

In the crystal vibrator 6, a groove 625 along the holding part 120 is provided to an upper surface 621A of a crystal substrate 621 of a lower lid 620. The groove 625 is provided to be recessed in such a manner as to open toward an upper lid 630. A groove 635 along the holding part 120 is provided to an upper surface 631B of a crystal substrate 631 of the upper lid 630. The groove 635 is provided to be recessed in such a manner as to open toward the lower lid 620. When seen in plan view, the grooves 625 and 635 are provided to the frame-shaped region surrounding the vibration part 110. Each of the grooves 625 and 635 is provided continuously along the frame parts 121A, 121C, and 121D. Each of the grooves 625 and 635 is provided discontinuously along the frame part 121B in such a manner as to avoid a region overlapping the part where the support arm 130 and the holding part 120 are connected. When seen in plan view, the groove 625 and the groove 635 overlap each other.

When the lower bonding part 40 is provided with a paste-like adhesive, the groove 625 restricts wet spreading of the adhesive on the lower lid 620 and suppresses an increase in surface area of the lower bonding part 40. Similarly, the groove 635 restricts wet spreading of the adhesive on the upper lid 630 and suppresses an increase in surface area of the upper bonding part 50. As a result, generation of outgas from the lower bonding part 40 and the upper bonding part 50 is suppressed. Therefore, fluctuation of frequency characteristics caused by attachment of outgas to the vibration part 110 is suppressed, and the crystal vibrator 6 has improved reliability.

Note that each of the grooves 625 and 635 may be provided discontinuously in the region along the frame parts 121A, 121C, and 121D. Further, in the region along the frame part 121B, each of the grooves 625 and 635 may be provided discontinuously outside of the region overlapping the part where the support arm 130 and the holding part 120 are connected.

Note that, instead of the grooves 625 and 635, projecting bank parts may be provided as long as structural parts that restrict wet spreading of the adhesive are provided to the lower lid 620 and the upper lid 630. Further, both the recessed grooves 625 and 635 and the projecting bank parts may be provided to the lower lid 620 and the upper lid 630.

Note that herein a crystal vibration element (quartz crystal resonator) including a crystal substrate (quartz crystal element) as a piezoelectric substrate (piezoelectric element) has been described as an example, but the piezoelectric vibration element (piezoelectric vibrator) is not limited thereto. Examples of the piezoelectric substrate that is suitably used for the piezoelectric vibrator according to this embodiment include piezoelectric ceramics such as PZT and aluminum nitride, and piezoelectric single crystals such as lithium niobate and lithium tantalate, but are not limited thereto and can be selected as appropriate.

The embodiments according to the present disclosure can be appropriately applied without particular limitation as long as the embodiments are applied to a device that performs electro-mechanical energy conversion by a piezoelectric effect, such as a timing device, a sound producing device, an oscillator, or a load sensor.

As described above, according to a mode of the present disclosure, a piezoelectric vibrator capable of achieving an improvement in reliability can be provided.

Note that the embodiments described above are for facilitating understanding of the present disclosure, and not for limiting interpretation of the present disclosure. The present disclosure may be changed/modified without departing from the spirit of the present disclosure and includes equivalents thereof. That is, the scope of the present disclosure includes designs obtained by appropriately changing the embodiments and/or modifications by those skilled in the art as long as the designs include the features of the present disclosure. For example, each component included in the embodiments and/or modifications, and the arrangement, material, condition, shape, size, and the like of the component are not limited to those illustrated, and can be changed as appropriate. In addition, the embodiments and modifications are illustrative, and it goes without saying that the configurations described in different embodiments and/or modifications can be partially substituted or combined, and the substitutions or combinations are also included within the scope of the present disclosure as long as they include the features of the present disclosure.

### REFERENCE SIGNS LIST

1 crystal vibrator
10 crystal vibration element
11 crystal substrate
110 vibration part
120 holding part
130 support arm
20 lower lid
30 upper lid
40 lower bonding part
50 upper bonding part
60 lower reinforcement part
70 upper reinforcement part
11A, 12A, 13A, 21A, 31A upper surface
11B, 12B, 13B, 21B, 31B lower surface
14a first excitation electrode
14b second excitation electrode
15a first extraction electrode
15b second extraction electrode
16a first connection electrode
16b second connection electrode

1. A piezoelectric vibrator comprising:
a piezoelectric vibration element including:
a vibration part;
a holding part disposed in at least a part of a frame-shaped region surrounding the vibration part such that the holding part has a gap from the vibration part; and
a support arm coupling the vibration part to the holding part to support the vibration part;
a first substrate opposing a first side of the piezoelectric vibration element;
a second substrate opposing a second side of the piezoelectric vibration element opposite from the first substrate;
a first bonding part bonding the holding part of the piezoelectric vibration element to the first substrate;
a second bonding part bonding the holding part of the piezoelectric vibration element to the second substrate; and a reinforcement part comprising resin and covering at least a part of the support arm.

2. The piezoelectric vibrator according to claim 1, wherein the reinforcement part comprises:
a first reinforcement part coupling the support arm to the first substrate; and
a second reinforcement part coupling the support arm to the second substrate.

3. The piezoelectric vibrator according to claim 2, wherein the support arm comprises:
a first main surface opposed to the first substrate,
a second main surface opposed to the second substrate,
a first side surface coupling the first main surface to the second main surface, and
a second side surface coupling the first main surface to the second main surface on an opposite side from the first side surface,
the first reinforcement part extends from a first end portion of the first main surface on a side of the first side surface to a second end portion of the first main surface on a side of the second side surface, and
the second reinforcement part extends from a third end portion of the second main surface on the side of the first side surface to a fourth end portion of the second main surface on the side of the second side surface.

4. The piezoelectric vibrator according to claim 2, wherein the first reinforcement part and the second reinforcement part are connected to each other at a connection of the support arm with the holding part.

5. The piezoelectric vibrator according to claim 2, wherein the first reinforcement part and the second reinforcement part are separated from each other.

6. The piezoelectric vibrator according to claim 1, wherein the reinforcement part covers a corner of the support arm at a connection with the holding part.

7. The piezoelectric vibrator according to claim 1, wherein the reinforcement part is connected to at least one of the first bonding part and the second bonding part.

8. The piezoelectric vibrator according to claim 1, wherein the reinforcement part extends to a connection of the support arm with the vibration part.

9. The piezoelectric vibrator according to claim 1, wherein the reinforcement part is separated from both the first bonding part and the second bonding part.

10. The piezoelectric vibrator according to claim 1, wherein the first substrate includes, on a side thereof facing the piezoelectric vibration element, a first cavity larger than the vibration part in plan view, and
the second substrate includes, on a side thereof facing the piezoelectric vibration element, a second cavity larger than the vibration part in the plan view.

11. The piezoelectric vibrator according to claim 1, wherein the vibration part comprises a center portion having an excitation electrode and a peripheral portion surrounding the center portion, and
wherein an opening is defined between the center portion of the vibration part and the support arm, the opening opening toward both the first substrate and the second substrate.

12. The piezoelectric vibrator according to claim 11, wherein when a longitudinal direction of the opening in plan view is defined as a width direction,
the support arm comprises a first side surface on a first side in the width direction and a second side surface on a second side opposite to the first side surface in the width direction,
the opening includes a first inner side surface on the first side in the width direction and a second inner side surface on the second side in the width direction,
the first side surface is located toward the second inner side surface with respect to the first inner side surface, and
the second side surface is located toward the first inner side surface with respect to the second inner side surface.

13. The piezoelectric vibrator according to claim 1, wherein each of the first substrate and the second substrate includes, on a side thereof facing the piezoelectric vibration element, a groove at a part of a frame-shaped region surrounding the vibration part in plan view, and
the groove is disposed so as to avoid a region overlapping a connection between the support arm and the holding part in the plan view.

14. The piezoelectric vibrator according to claim 1, wherein the reinforcement part comprises a material that is a same material of the first bonding part and the second bonding part.

15. The piezoelectric vibrator according to claim 1, wherein the piezoelectric vibration element comprises a crystal substrate extends continuously across the vibration part, the holding part, and the support arm.

16. The piezoelectric vibrator according to claim 15, wherein the crystal substrate is an AT-cut crystal substrate.

17. A piezoelectric vibrator comprising:
a piezoelectric vibration element comprising:
a vibration part;
a holding part disposed in at least a part of a frame-shaped region surrounding the vibration part with a gap therebetween; and
a support arm coupling the vibration part to the holding part;
a first substrate opposed to a first side of the piezoelectric vibration element;
a second substrate opposed to a second side of the piezoelectric vibration element opposite from the first substrate;
a first bonding part bonding the holding part to the first substrate;
a second bonding part bonding the holding part to the second substrate;
a first reinforcement part comprising resin, and coupling the support arm to the first substrate so as to restrict displacement of the support arm toward the first substrate; and
a second reinforcement part comprising resin, and coupling the support arm to the second substrate so as to restrict displacement of the support arm toward the second substrate.

18. The piezoelectric vibrator according to claim 17, wherein an elastic modulus of the first reinforcement part and the second reinforcement part is smaller than an elastic modulus of a piezoelectric substrate of the piezoelectric vibration element.

19. A piezoelectric vibrator comprising:
a piezoelectric vibration element comprising a piezoelectric substrate, the piezoelectric substrate comprising:
a vibration part having a first main surface and a second main surface;
a holding part disposed in a frame-shaped region surrounding the vibration part with a gap therebetween; and
a support arm coupling the vibration part to the holding part;
a first substrate opposed to the first main surface of the vibration part;
a second substrate opposed to the second main surface of the vibration part;
a first bonding part bonding the holding part to the first substrate;
a second bonding part bonding the holding part to the second substrate; and
a reinforcement part comprising resin and covering corners of the support arm where the support arm is connected to the holding part.

20. The piezoelectric vibrator according to claim 19, wherein the reinforcement part covers the corners of the support arm where the first main surface of the support arm meets side surfaces of the support arm and the corners of the support arm where the second main surface of the support arm meets the side surfaces of the support arm.
